(19) United States
(12) Patent Application Publication
(10) Pub. No.: US 2026/0136500 A1
(43) Pub. Date: May 14, 2026

(54) ENCLOSED LIQUID-COOLING COOLER

(71) Applicant: AMULAIRE THERMAL TECHNOLOGY, INC., New Taipei City (TW)

(72) Inventors: CHING-MING YANG, New Taipei City (TW); KUO-WEI LEE, New Taipei City (TW); MING-HSUAN CHANG, Taoyuan City (TW)

(21) Appl. No.: 18/947,257

(22) Filed: Nov. 14, 2024

(51) Int. Cl. H05K 7/20

(52) U.S. Cl. CPC H05K 7/2039; H05K 7/20272

(57) ABSTRACT

An enclosed liquid-cooling cooler includes a copper heat sink and an aluminum heat sink, and a flow channel is formed therebetween to enable flowing of a coolant. The copper and aluminum heat sinks are bonded by friction stir welding, so as to form one or more bonding surfaces. One or more gaps are formed between the copper and aluminum heat sinks. An electroless-nickel-plating embedding layer is plated within the gap, such that the gap is less than 0.1 mm. A copper surface of the copper heat sink and an aluminum surface of the aluminum heat sink that come into contact with the coolant are each plated with at least one electroless-nickel-plating surface layer having a thickness of between 5 μm and 13 μm, such that the electroless-nickel-plating surface layer replaces the copper surface and the aluminum surface for contacting the coolant. Accordingly, potential difference corrosion can be prevented.

### FIELD OF THE DISCLOSURE

The present disclosure relates to a liquid-cooling cooler, and more particularly to an enclosed liquid-cooling cooler.

### BACKGROUND OF THE DISCLOSURE

In the current marketplace, there is an increasingly high requirement on a liquid-cooling cooler for an automotive insulated-gate bipolar transistor (IGBT) or automotive advanced driver-assistance systems (ADAS). However, a heat dissipation ability of an all-aluminum liquid-cooling cooler is limited, and an all-copper liquid-cooling cooler is costly and heavy in weight. Furthermore, potential difference corrosion may occur to a copper-aluminum-bonded liquid-cooling cooler. Therefore, the existing liquid-cooling cooler fails to meet the requirements.

### SUMMARY OF THE DISCLOSURE

In response to the above-referenced technical inadequacies, the present disclosure provides an enclosed liquid-cooling cooler.

In order to solve the above-mentioned problems, one of the technical aspects adopted by the present disclosure is to provide an enclosed liquid-cooling cooler, which includes a copper heat sink and an aluminum heat sink. The copper heat sink is formed by copper or a copper alloy, and has a plurality of copper fins. The aluminum heat sink is formed by aluminum or an aluminum alloy. A flow channel is formed between the copper heat sink and the aluminum heat sink to enable flowing of a coolant. The copper heat sink and the aluminum heat sink are bonded by friction stir welding, so as to form one or more bonding surfaces. One or more gaps are formed between the copper heat sink and the aluminum heat sink, and an electroless-nickel-plating embedding layer is plated within the gap, such that the gap is less than 0.1 mm. A copper surface of the copper heat sink and an aluminum surface of the aluminum heat sink that come into contact with the coolant are each plated with at least one electroless-nickel-plating surface layer having a thickness of between 5 μm and 13 μm, such that the at least one electroless-nickel-plating surface layer replaces the copper surface and the aluminum surface for contacting the coolant. A phosphorus content of the at least one electroless-nickel-plating surface layer is greater than 5.5 wt %.

In one of the possible or preferred embodiments, the aluminum heat sink has a plurality of water holes that are in spatial communication with the flow channel.

In one of the possible or preferred embodiments, the copper fin is one of a pin fin, a skived fin, and a wavy fin.

In one of the possible or preferred embodiments, the gap that is plated with the electroless-nickel-plating embedding layer is horizontally oriented, and a normal of the horizontally-oriented gap is perpendicular to a flowing direction of the coolant.

In order to solve the above-mentioned problems, another one of the technical aspects adopted by the present disclosure is to provide an enclosed liquid-cooling cooler, which includes a copper heat sink and an aluminum heat sink. The copper heat sink is formed by copper or a copper alloy, and has a plurality of copper fins. The aluminum heat sink is formed by aluminum or an aluminum alloy. A flow channel is formed between the copper heat sink and the aluminum heat sink to enable flowing of a coolant. The copper heat sink and the aluminum heat sink are bonded by friction stir welding, so as to form one or more bonding surfaces. A copper surface of the copper heat sink that comes into contact with the coolant is plated with at least one pure aluminum or pure titanium plating layer having a thickness of less than 10 μm, a purity of the at least one pure aluminum or pure titanium plating layer is greater than 99%, and the at least one pure aluminum or pure titanium plating layer replaces the copper surface for contacting the coolant. At least one portion of an aluminum surface of the aluminum heat sink that comes into contact with the coolant is not covered by any plating layer.

In one of the possible or preferred embodiments, the aluminum heat sink is formed by bonding a first aluminum member and a second aluminum member, and a plurality of water holes are formed on at least one of the first aluminum member or the second aluminum member.

In one of the possible or preferred embodiments, the first aluminum member and the second aluminum member are bonded by friction stir welding.

In one of the possible or preferred embodiments, the at least one pure aluminum or pure titanium plating layer is a coating layer formed by physical vapor deposition (PVD).

In one of the possible or preferred embodiments, one or more vertically-oriented gaps are formed between the copper heat sink and the aluminum heat sink, such that a partial portion of the at least one pure aluminum or pure titanium plating layer is plated into the vertically-oriented gap, and a normal of the gap that is plated with the partial portion of the at least one pure aluminum or pure titanium plating layer is perpendicular to a height direction of the copper fins.

In one of the possible or preferred embodiments, the gap that is plated with the partial portion of the at least one pure aluminum or pure titanium plating layer is less than one half of the thickness of the at least one pure aluminum or pure titanium plating layer.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic cross-sectional view of a copper heat sink and an aluminum heat sink of an enclosed liquid-cooling cooler before bonding according to a first embodiment of the present disclosure;

FIG. 2 is a schematic top view of the copper heat sink and the aluminum heat sink of the enclosed liquid-cooling cooler after bonding according to the first embodiment of the present disclosure;

FIG. 3 is a schematic cross-sectional view taken along line III-III of FIG. 2;

FIG. 4 is a schematic enlarged view of part IV of FIG. 3;

FIG. 5 is a schematic cross-sectional view of the copper heat sink and the aluminum heat sink of the enclosed liquid-cooling cooler before bonding according to a second embodiment of the present disclosure;

FIG. 6 is a schematic cross-sectional view of the copper heat sink and the aluminum heat sink of the enclosed liquid-cooling cooler after bonding according to the second embodiment of the present disclosure;

FIG. 7 is a schematic enlarged view of part VII of FIG. 6; and

FIG. 8 is a schematic cross-sectional view of the copper heat sink and the aluminum heat sink of the enclosed liquid-cooling cooler after bonding according to a third embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### First Embodiment

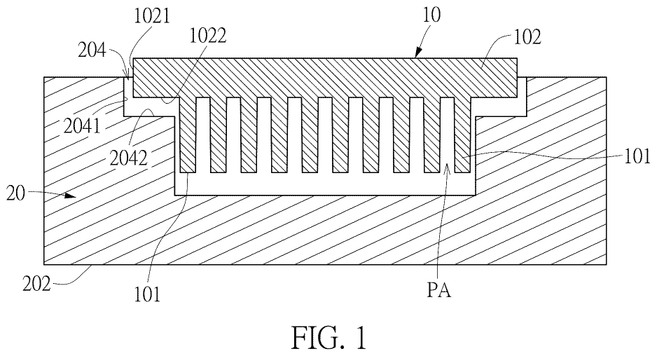

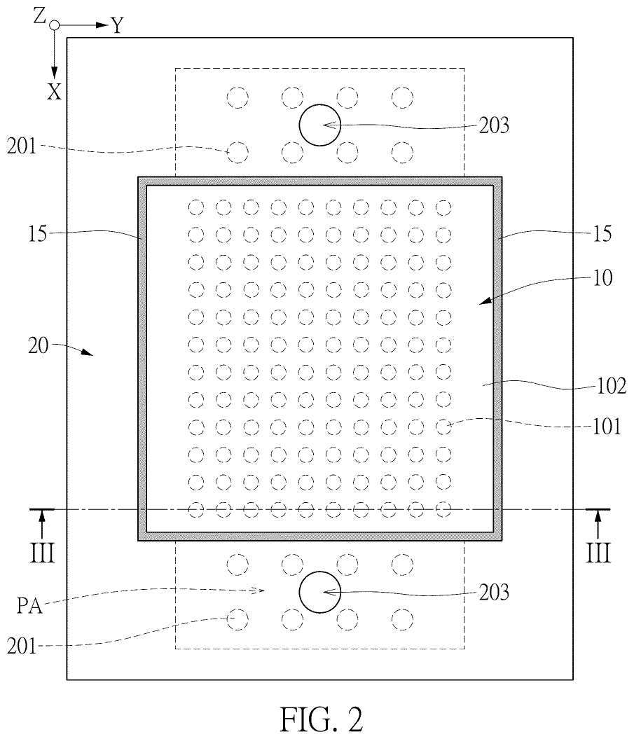

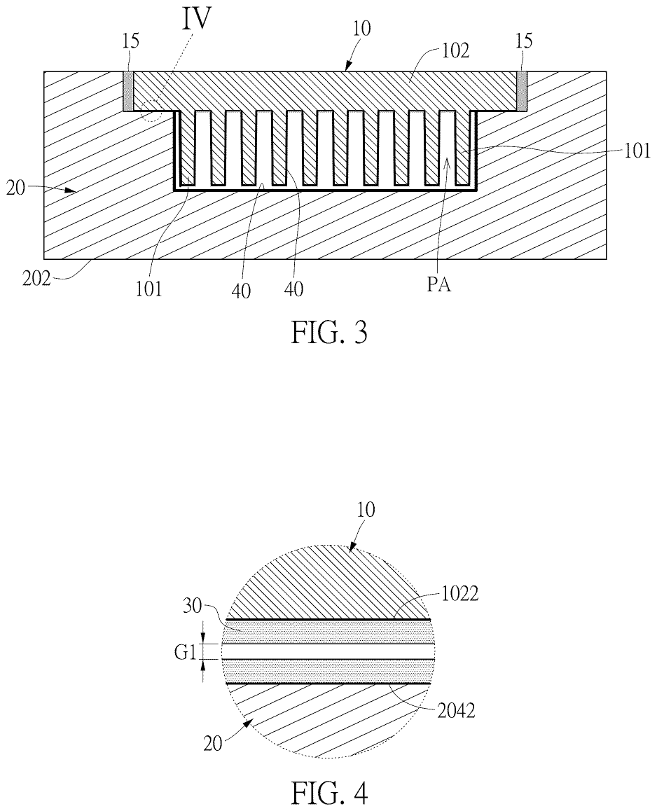

Reference is made to FIG. 1 to FIG. 4, which show a first embodiment of the present disclosure. The embodiment of the present disclosure provides an enclosed liquid-cooling cooler, which essentially includes a copper heat sink 10 and an aluminum heat sink 20 that are bonded to each other.

The copper heat sink 10 can be a copper heat sink that is formed by copper or a copper alloy, and can be a copper heat sink that has a plurality of copper fins 101. The aluminum heat sink 20 can be an aluminum heat sink that is formed by aluminum or an aluminum alloy. The aluminum heat sink 20 can be an integrally-formed aluminum member, and can also be formed by bonding a plurality of aluminum members.

A flow channel PA is formed between the copper heat sink 10 and the aluminum heat sink 20 that are bonded to each other, so as to enable flowing of a coolant. The coolant within the flow channel PA can be water or ethylene glycol. Specifically, the copper heat sink 10 and the aluminum heat sink 20 are bonded by friction stir welding, so as to form one or more bonding surfaces 15. The bonding surface 15 is a specific solid-state welded portion that can only be formed by friction stir welding, so as to enable bonding of the copper heat sink 10 and the aluminum heat sink 20 (which are two dissimilar metal members). When the copper heat sink 10 and the aluminum heat sink 20 are bonded by friction stir welding, gaps exist between the copper heat sink 10 and the aluminum heat sink 20 at locations where bonding is not achievable by friction stir welding. Under the influence of the coolant, galvanic corrosion (i.e., potential difference corrosion) may occur between the copper heat sink 10 and the aluminum heat sink 20, thereby reducing product reliability. Hence, in the present embodiment, an electroless-nickel-plating embedding layer 30 is plated within a gap G1 between the copper heat sink 10 and the aluminum heat sink 20, such that the gap G1 is less than 0.1 mm. Furthermore, a copper surface of the copper heat sink 10 and an aluminum surface of the aluminum heat sink 20 that come into contact with the coolant are each plated with at least one electroless-nickel-plating surface layer 40 having an extremely small thickness of between 5 μm and 13 μm, such that the electroless-nickel-plating surface layer 40 replaces the copper surface of the copper heat sink 10 and the aluminum surface of the aluminum heat sink 20 for contacting the coolant. A phosphorus content of the electroless-nickel-plating surface layer 40 is greater than 5.5 wt %. In this way, the occurrence of galvanic corrosion to the copper surface of the copper heat sink 10 and the aluminum surface of the aluminum heat sink 20 under the influence of the coolant can be effectively prevented, thereby enhancing product reliability. At the same time, the ability of the enclosed liquid-cooling cooler to dissipate heat of a heat source area can indeed be improved by the copper heat sink 10.

Specifically, the copper heat sink 10 of the present embodiment can have a copper base 102, and the copper fins 101 can be integrally formed on the copper base 102. The copper fin 101 can be a pin fin in the present embodiment, but can also be a skived fin or a wavy fin. The copper fins 101 and the copper base 102 can be a forged copper alloy member formed by forging, but can also be formed by metal injection molding (MIM). The aluminum heat sink 20 of the present embodiment can be an aluminum alloy member that has a plurality of aluminum fins 201. The aluminum heat sink 20 can have an aluminum cover 202, and the aluminum fins 201 can be integrally formed on the aluminum cover 202. The aluminum fin 201 can be a pin fin in the present embodiment, but can also be a skived fin or a wavy fin. The aluminum fins 201 and the aluminum cover 202 can be a die-casting aluminum alloy member formed by die casting. Furthermore, the aluminum heat sink 20 can have a plurality of water holes 203 that are formed on the aluminum cover 202 and in spatial communication with the flow channel PA. One of the water holes 203 can be a water inlet, and another one of the water holes 203 can be a water outlet.

More specifically, the aluminum heat sink 20 has an aluminum through groove 204 that is formed on the aluminum cover 202 and corresponds to the copper base 102, and the aluminum through groove 204 has a vertical groove surface 2041 and a horizontal groove surface 2042 that are adjoined to each other. The copper base 102 has a vertical surface 1021 and a horizontal surface 1022 that are adjoined to each other. Through friction stir welding, the vertical surface 1021 of the copper base 102 and the vertical groove surface 2041 of the aluminum through groove 204 are formed into the bonding surface 15 of the copper heat sink 10 and the aluminum heat sink 20. The horizontal surface 1022 of the copper base 102 and the horizontal groove surface 2042 of the aluminum through groove 204 act as a joining surface of the copper heat sink 10 and the aluminum heat sink 20, and the extremely small and horizontally-oriented gap G1 is formed between the horizontal surface 1022 of the copper base 102 and the horizontal groove surface 2042 of the aluminum through groove 204. That is, the gap G1 that is plated with the electroless-nickel-plating embedding layer 30 is horizontally oriented, and a normal of the horizontally-oriented gap G1 is perpendicular to a flowing direction (i.e., an X-axis direction) of the coolant, so as to prevent generation of potential difference corrosion due to the copper heat sink 10 and the aluminum heat sink 20 simultaneously contacting the coolant.

### Second Embodiment

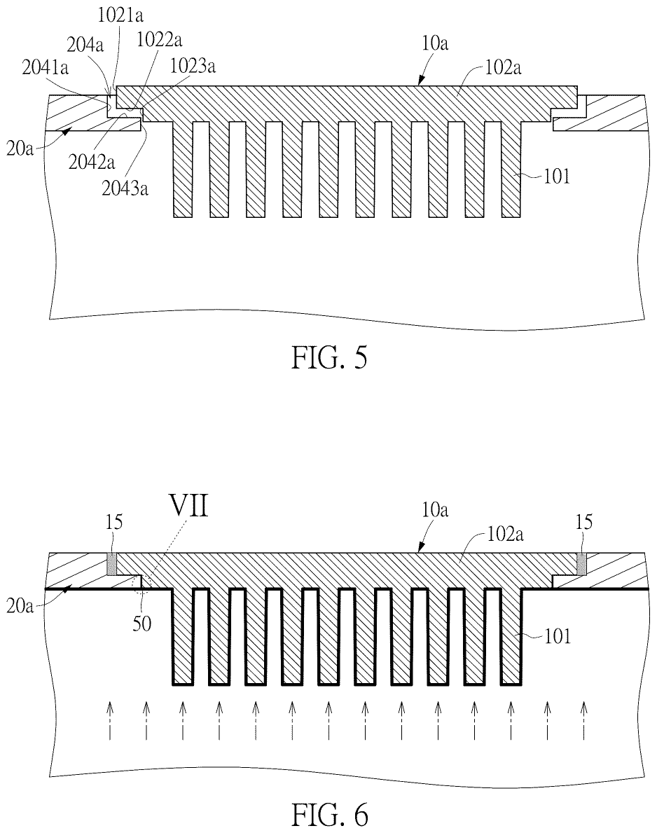

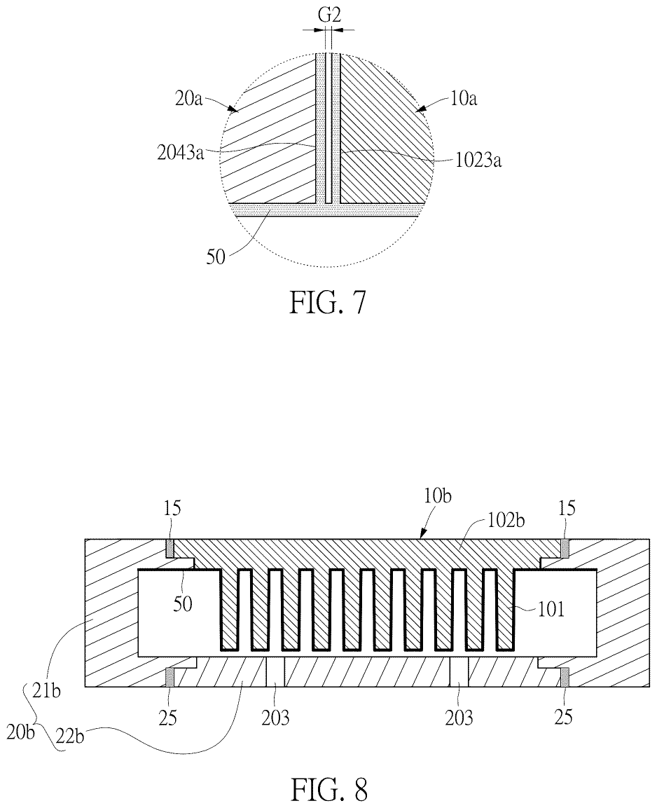

Reference is made to FIG. 5 to FIG. 7, which show a second embodiment of the present disclosure. The present embodiment is substantially the same as the first embodiment, and differences therebetween will be described below.

In the present embodiment, the size (a length or a width) of a copper heat sink 10a is greater than that of the copper heat sink 10 in FIG. 3. When the size of the copper heat sink 10a is increased, the costs for electroless plating may become too high. Hence, partial plating is adopted in the present embodiment. However, an electric potential of a metal that is to be plated with the copper heat sink 10a needs to be close to that of an aluminum heat sink 20a, such that potential difference corrosion can be prevented.

Based on the above, a copper surface of the copper heat sink 10a that comes into contact with the coolant is plated with at least one pure aluminum or pure titanium plating layer 50 having a thickness of less than 10 μm in the present embodiment. A purity of the pure aluminum or pure titanium plating layer 50 is greater than 99%, and the pure aluminum or pure titanium plating layer 50 replaces the copper surface of the copper heat sink 10a for contacting the coolant. At least one portion of an aluminum surface of the aluminum heat sink 20a that comes into contact with the coolant is not covered by any plating layer. In this way, a pure aluminum metal or a pure titanium metal can be specifically and partially plated on the copper surface of the copper heat sink 10a that will come into contact with the coolant (i.e., being used in an economical manner), thereby achieving heat dissipation and preventing potential difference corrosion at the same time.

Since the pure aluminum metal or the pure titanium metal cannot be plated on the copper surface of the copper heat sink 10a by electroless plating, the pure aluminum or pure titanium plating layer 50 of the present embodiment is a coating layer formed by physical vapor deposition (PVD), such as sputtering, arc ion plating (AIP), and evaporation. When physical vapor deposition is applied, a plating direction is a vertical direction (i.e., an arrow direction as shown in FIG. 6), such that the coating layer formed by physical vapor deposition is unable to cover a corner of a workpiece.

Hence, one or more vertically-oriented gaps G2 are formed between the copper heat sink 10a and the aluminum heat sink 20a in the present embodiment, such that a partial portion of the pure aluminum or pure titanium plating layer 50 is vertically plated into the vertically-oriented gap G2 by physical vapor deposition. In addition, a normal of the vertically-oriented gap G2 that is plated with the partial portion of the pure aluminum or pure titanium plating layer 50 is perpendicular to a height direction of the copper fins 101.

Specifically, in order for the partial portion of the pure aluminum or pure titanium plating layer 50 to be vertically plated into the gap G2 by physical vapor deposition, a side surface of a copper base 102a is a stepped surface in the present embodiment. The stepped surface includes a first vertical surface 1021a, a horizontal surface 1022a, and a second vertical surface 1023a that are adjoined to each other. The aluminum heat sink 20a has an aluminum through groove 204a that is formed on an aluminum cover and corresponds to the copper base 102a, such that the aluminum through groove 204a has a corresponding stepped groove surface. The stepped groove surface includes a first vertical groove surface 2041a, a horizontal groove surface 2042a, and a second vertical groove surface 2043a that are adjoined to each other. The first vertical surface 1021a of the copper base 102a and the first vertical groove surface 2041a of the aluminum through groove 204a are formed into the bonding surface 15 of the copper heat sink 10a and the aluminum heat sink 20a by friction stir welding. The extremely small and vertically-oriented gap G2 is formed between the second vertical surface 1023a of the copper base 102a and the second vertical groove surface 2043a of the aluminum through groove 204a. Furthermore, the gap G2 is less than 2.5 μm, and is less than one half of the thickness of the pure aluminum or pure titanium plating layer 50. Accordingly, the partial portion of the pure aluminum or pure titanium plating layer 50 can be vertically plated into and cover the vertically-oriented gap G2 by physical vapor deposition, so as to prevent generation of potential difference corrosion due to the copper heat sink 10a and the aluminum heat sink 20a simultaneously contacting the coolant.

### Third Embodiment

Reference is made to FIG. 8, which shows a third embodiment of the present disclosure. The present embodiment is substantially the same as the second embodiment, and differences therebetween will be described below.

In the present embodiment, an aluminum heat sink 20b is formed by bonding a first aluminum member 21b and a second aluminum member 22b, and the water holes 203 are formed on the first aluminum member 21b or the second aluminum member 22b. In the present embodiment, the water holes 203 are formed on the second aluminum member 22b, and the second aluminum member 22b can be an aluminum cover. The first aluminum member 21b of the aluminum heat sink 20b and a copper base 102b of the copper heat sink 10b can be bonded by friction stir welding, so as to form the one or more bonding surfaces 15. In addition, the first aluminum member 21b and the second aluminum member 22b of the aluminum heat sink 20b can be bonded by friction stir welding, so as to form one or more bonding surfaces 25. As such, even if gaps exist at or near a bonding position of the first aluminum member 21b and the second aluminum member 22b, potential difference corrosion will not occur.

### Beneficial Effects of the Embodiments

In conclusion, the enclosed liquid-cooling cooler provided by the present disclosure includes a copper heat sink and an aluminum heat sink. A flow channel is formed between the copper heat sink and the aluminum heat sink to enable flowing of a coolant. The copper heat sink and the aluminum heat sink are bonded by friction stir welding, so as to form one or more bonding surfaces. One or more gaps are formed between the copper heat sink and the aluminum heat sink, and an electroless-nickel-plating embedding layer is plated within the gap, such that the gap is less than 0.1 mm. A copper surface of the copper heat sink and an aluminum surface of the aluminum heat sink that come into contact with the coolant are each plated with at least one electroless-nickel-plating surface layer having a thickness of between 5 μm and 13 μm, such that the at least one electroless-nickel-plating surface layer replaces the copper surface and the aluminum surface for contacting the coolant. A phosphorus content of the at least one electroless-nickel-plating surface layer is greater than 5.5 wt %. Alternatively, the copper surface of the copper heat sink that comes into contact with the coolant is plated with at least one pure aluminum or pure titanium plating layer having a thickness of less than 10 μm, a purity of the at least one pure aluminum or pure titanium plating layer is greater than 99%, and the at least one pure aluminum or pure titanium plating layer replaces the copper surface for contacting the coolant. At least one portion of an aluminum surface of the aluminum heat sink that comes into contact with the coolant is not covered by any plating layer. In this way, the occurrence of galvanic corrosion to the copper surface of the copper heat sink and the aluminum surface of the aluminum heat sink under the influence of the coolant can be effectively prevented, thereby enhancing product reliability. At the same time, the ability of the enclosed liquid-cooling cooler to dissipate heat of a heat source area can indeed be improved by the copper heat sink.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. An enclosed liquid-cooling cooler, comprising:
a copper heat sink, wherein the copper heat sink is formed by copper or a copper alloy, and has a plurality of copper fins; and
an aluminum heat sink, wherein the aluminum heat sink is formed by aluminum or an aluminum alloy;
wherein a flow channel is formed between the copper heat sink and the aluminum heat sink to enable flowing of a coolant; wherein the copper heat sink and the aluminum heat sink are bonded by friction stir welding, so as to form one or more bonding surfaces; wherein one or more gaps are formed between the copper heat sink and the aluminum heat sink, and an electroless-nickel-plating embedding layer is plated within the gap, such that the gap is less than 0.1 mm; wherein a copper surface of the copper heat sink and an aluminum surface of the aluminum heat sink that come into contact with the coolant are each plated with at least one electroless-nickel-plating surface layer having a thickness of between 5 μm and 13 μm, such that the at least one electroless-nickel-plating surface layer replaces the copper surface and the aluminum surface for contacting the coolant; wherein a phosphorus content of the at least one electroless-nickel-plating surface layer is greater than 5.5 wt %.

2. The enclosed liquid-cooling cooler according to claim 1, wherein the aluminum heat sink has a plurality of water holes that are in spatial communication with the flow channel.

3. The enclosed liquid-cooling cooler according to claim 1, wherein the copper fin is one of a pin fin, a skived fin, and a wavy fin.

4. The enclosed liquid-cooling cooler according to claim 1, wherein the aluminum heat sink has a plurality of aluminum fins that are integrally formed, and the aluminum fin is one of a pin fin, a skived fin, and a wavy fin.

5. The enclosed liquid-cooling cooler according to claim 1, wherein the gap that is plated with the electroless-nickel-plating embedding layer is horizontally oriented, and a normal of the horizontally-oriented gap is perpendicular to a flowing direction of the coolant.

6. An enclosed liquid-cooling cooler, comprising:
a copper heat sink, wherein the copper heat sink is formed by copper or a copper alloy, and has a plurality of copper fins; and
an aluminum heat sink, wherein the aluminum heat sink is formed by aluminum or an aluminum alloy;
wherein a flow channel is formed between the copper heat sink and the aluminum heat sink to enable flowing of a coolant; wherein the copper heat sink and the aluminum heat sink are bonded by friction stir welding, so as to form one or more bonding surfaces; wherein a copper surface of the copper heat sink that comes into contact with the coolant is plated with at least one pure aluminum or pure titanium plating layer having a thickness of less than 10 μm, a purity of the at least one pure aluminum or pure titanium plating layer is greater than 99%, and the at least one pure aluminum or pure titanium plating layer replaces the copper surface for contacting the coolant; wherein at least one portion of an aluminum surface of the aluminum heat sink that comes into contact with the coolant is not covered by any plating layer.

7. The enclosed liquid-cooling cooler according to claim 6, wherein the aluminum heat sink has a plurality of water holes that are in spatial communication with the flow channel.

8. The enclosed liquid-cooling cooler according to claim 7, wherein the aluminum heat sink is formed by bonding a first aluminum member and a second aluminum member, and the water holes are formed on at least one of the first aluminum member or the second aluminum member.

9. The enclosed liquid-cooling cooler according to claim 8, wherein the first aluminum member and the second aluminum member are bonded by friction stir welding.

10. The enclosed liquid-cooling cooler according to claim 6, wherein the copper fin is one of a pin fin, a skived fin, and a wavy fin.

11. The enclosed liquid-cooling cooler according to claim 6, wherein the aluminum heat sink has a plurality of aluminum fins that are integrally formed, and the aluminum fin is one of a pin fin, a skived fin, and a wavy fin.

12. The enclosed liquid-cooling cooler according to claim 6, wherein the at least one pure aluminum or pure titanium plating layer is a coating layer formed by physical vapor deposition (PVD).

13. The enclosed liquid-cooling cooler according to claim 6, wherein one or more vertically-oriented gaps are formed between the copper heat sink and the aluminum heat sink, such that a partial portion of the at least one pure aluminum or pure titanium plating layer is plated into the vertically-oriented gap, and a normal of the gap that is plated with the partial portion of the at least one pure aluminum or pure titanium plating layer is perpendicular to a height direction of the copper fins.

14. The enclosed liquid-cooling cooler according to claim 13, wherein the gap that is plated with the partial portion of the at least one pure aluminum or pure titanium plating layer is less than one half of the thickness of the at least one pure aluminum or pure titanium plating layer.
